(19) United States
(12) Patent Application Publication
(10) Pub. No.: US 2008/0197934 A1
(43) Pub. Date: Aug. 21, 2008

(54) INTEGRATABLE CIRCUIT ARRANGEMENT AND INTEGRATED CIRCUIT

(76) Inventor: Samir El Rai, Colorado Springs, CO (US)

Correspondence Address: Muncy, Geissler, Olds & Lowe, PLLC, P.O. BOX 1364, FAIRFAX, VA, 22038-1364, US

(21) Appl. No.: 11/964,698

(22) Filed: Dec. 26, 2007

Related U.S. Application Data
(60) Provisional application No. 60/878,673, filed on Jan. 5, 2007.

(30) Foreign Application Priority Data
Dec. 22, 2006 (DE) DE 102006060870

(51) Int. Cl. H03B 5/12

(52) U.S. Cl. 331/179

(57) ABSTRACT

An integratable circuit arrangement is provided having a circuit unit, controllable by means of at least one control voltage, to provide a high-frequency output signal dependent on the at least one control voltage. According to the invention, (a) a clocked DC converter is provided, which is formed to provide at least one control voltage, depending on a control signal applied at its clock input, and (b) the circuit arrangement is formed to supply the clock input with a control signal, dependent on the high-frequency output signal.

This nonprovisional application claims priority to German Patent Application No. DE 102006060870, which was filed in Germany on Dec. 22, 2006, and to U.S. Provisional Application No. 60/878,673, which was filed on Jan. 5, 2007, and which are both herein incorporated by reference.

### BACKGROUND OF THE INVENTION

1. Field of the Invention

The present invention relates to an integratable circuit arrangement. The invention relates further to an integrated circuit (IC).

2. Description of the Background Art

The invention is within the field of integrated semiconductor circuits in which high-frequency signals, for example, in the microwave range, are processed. It is particularly in the field of integratable circuit arrangements for controlling a controllable circuit unit by means of at least one control voltage, the circuit unit providing a high-frequency output signal dependent on the control voltage(s).

Controllable circuit units of this type are required in many cases for processing high-frequency (HF) signals, e.g., in integrated HF front-end circuits, with whose help in transmitting/receiving devices of communication systems, an HF incoming signal, such as, e.g., a radio signal received over an antenna in the gigahertz range, is converted to a quadrature signal with a lower, fixed frequency. For example, controllable circuit units of this type can be voltage-controlled amplifiers, filters, or oscillators (VCO, voltage-controlled oscillator).

In prior-art integrated circuit arrangements, the control range (voltage swing) of the control voltage(s) is typically limited here to a relatively small range between a reference potential (ground) and an integrated circuit supply voltage. This leads disadvantageously to a limited tunability, i.e., to a relatively small width of the tuning range, and to low values for the quality of the controllable circuit unit. In addition, prior-art integrated circuit arrangements are relatively sensitive to additive disturbances, such as, e.g., noise in the control voltage(s).

### SUMMARY OF THE INVENTION

It is therefore an object of the present invention to provide an integratable circuit arrangement of the aforementioned type, which makes possible a higher quality and an improved tunability of the circuit unit, is less sensitive to additive interferences in the voltage(s), and nevertheless can be integrated simply and cost-effectively into a semiconductor circuit (IC).

The circuit arrangement of the invention comprises a circuit unit, controllable by means of at least one control voltage, to provide a high-frequency output signal, dependent on the at least one control voltage, and a clocked DC converter, which provides the at least one control voltage depending on a control signal applied at its clock input, the circuit arrangement being formed to supply the clock input with a control signal, dependent on the high-frequency output signal.

The integrated circuit of the invention has at least one circuit arrangement of this type.

In an embodiment, a clocked DC converter (DC/DC converter) is provided with a clock input and of supplying the clock input with a control signal, which depends on the high-frequency output signal of the circuit unit. As a result, several properties of the voltage-controlled circuit unit, such as, e.g., the quality, tunability, and robustness to control voltage additive disturbances, are advantageously improved. In addition, the circuit arrangement of the invention can be integrated simply and cost-effectively into a semiconductor circuit (IC).

In an embodiment, a matching unit, connected to the circuit unit and to the clock input, is provided, which is formed to change an amplitude and/or a frequency of the high-frequency output signal and to provide the resulting control signal. As a result, the voltage swing of the control voltage(s) is increased further, so that an especially good tunability and an. especially high value for the quality with a very good robustness to additive disturbances are made possible.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a first exemplary embodiment of a circuit arrangement of the invention with a voltage-controlled oscillator;

FIG. 2 shows a capacitive unit of the voltage-controlled oscillator of FIG. 1;

FIG. 3 shows a second exemplary embodiment of a circuit arrangement of the invention with a voltage-controlled amplifier; and

FIG. 4 shows a block diagram of a WiMax transceiver having a circuit arrangement of the invention.

### DETAILED DESCRIPTION

In the figures, the same and functionally identical elements and signals, if not specified otherwise, are provided with the same reference characters.

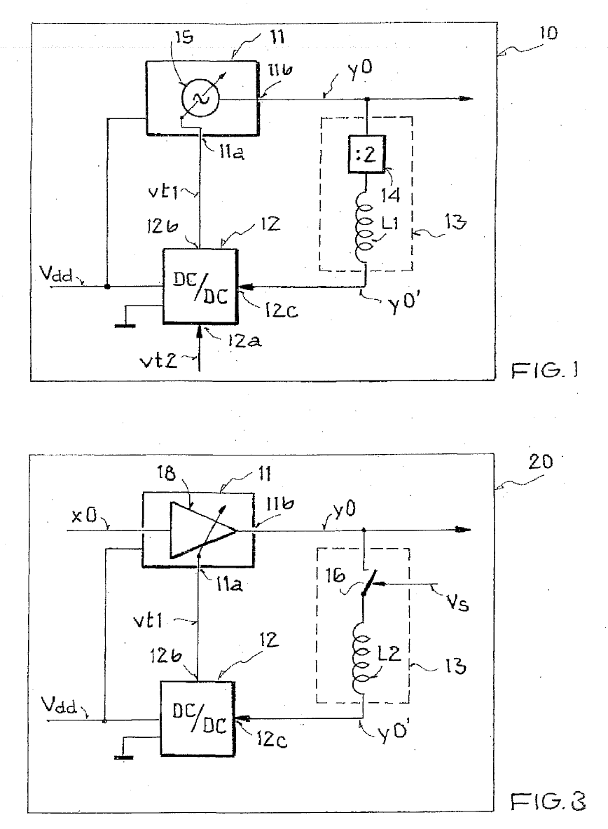

FIG. 1 shows a block diagram of a first exemplary embodiment of a circuit arrangement of the invention.

Integratable circuit arrangement 10 has a controllable (adjustable) circuit unit 11, a clocked DC converter (DC/DC converter) 12, and optionally a matching unit 13.

DC converter 12 has a clock input 12c and is connected via this input and optionally matching unit 13 to an output 11b of circuit unit 11. Moreover, DC converter 12 has an input for supplying the operating power (Vdd) and preferably at least one other input 12a. On the output side, DC converter 12 is connected via at least one output 12b to at least one control input 11a of circuit unit 11.

Controllable circuit unit 11 generates a high-frequency output signal y0, dependent on at least one control voltage vt1, and provides it at its output 11b. The control voltage(s) vt1 in this case can be formed continuous-value (analog) and/or discrete-value (digital, binary/two-level). Circuit unit 11 and DC converter 12 are supplied with operating power by means of a supply voltage Vdd of, for example, 3 V.

In the exemplary embodiment shown in FIG. 1, circuit unit 11 comprises a voltage-controlled oscillator 15 (VCO), which generates an output signal y0 with an adjustable frequency f0, which varies, for example, between 6.8 and 7.2 GHz depending on the value of the control voltage(s) vt1. Control voltages vt1, for example, are five control voltages vt1a, vt1b, . . . , vt1e, each of which can assume one of the two voltage values −3 V, +6 V, so that the maximum value (6 V) of the control voltages vt1, in terms of amount, exceeds the value of the supply voltage Vdd=3 V of the circuit arrangement. Each of the five control voltages vt1a, vt1b, . . . , vt1e here represents an assigned bit location of a word, with whose help precisely one of a total of 32 frequency values in the aforementioned frequency range is selected.

DC converter 12 converts the two input-side potential values 3 V (Vdd) and 0 V (ground) into two output-side potential values −3 V and 6 V, generates one or more control voltages vt1, each of which assumes, depending on the value of the assigned control voltage vt2, the lower output-side potential value of −3 V (if vt2=0 V) or the higher output-side potential value of 6 V (if vt2=3 V), and provides the control voltage(s) vt1 to control circuit unit 11, whereby only very low currents (leakage currents of transistors) flow. DC converter 12 is preferably made as a capacitive boost converter or capacitive inverting boost converter.

DC converter 12 generates the control voltage(s) vt1 depending on a control signal y0′ applied at its clock input 12c. Control signal y0′ supplied to clock input 12c depends on the high-frequency output signal y0 of circuit unit 11 and is derived from it. Control signal y0′ in this case is identical to the output signal y0 (without block 13) or is (preferably) derived by matching unit 13 from output signal y0.

If present, matching unit 13, connected to output 11b of circuit unit 11 and clock input 12c of DC converter 12, changes the amplitude A0 and/or the frequency f0 of the signal y0, applied at its input, and at its output provides the resulting control signal y0′ to control DC converter 12.

In this exemplary embodiment, matching unit 13 comprises a frequency divider 14, which halves the frequency f0 of output signal y0, and an inductor L1 connected downstream. Together with a capacitor, such as, e.g., the input capacitor of DC converter 12, or a transmission line, inductor L1 modifies the amplitude of its input signal. By means of this inductor L1, matching unit 13 amplifies, for example, the amplitude A0=3 V of signal y0 in such a way that control signal y0′ has an amplitude of A0′=8 V and thereby clearly exceeds the amplitude A0. The efficiency of DC converter 12 and the voltage swing of the control voltage(s) vt1 are advantageously increased further by this type of amplitude increase.

In other embodiments, integer divider values N are provided in the frequency division, so that the frequency f0 of output signal y0 coincides with an integer multiple N=1, 2, 3, . . . of the frequency f0′ of control signal y0′. Preferably, f0 coincides with the onefold or twofold value of f0′.

In another embodiment (not shown), matching unit 13 has no frequency divider, so that the frequencies f0 and f0′ of the signals y0 or y0′, respectively, coincide with each other.

In another embodiment, which is also not shown, circuit unit 11 has a frequency divider, which is connected after VCO 15 and, for example, halves the frequency of the VCO output signal and provides the signal y0. Preferably, frequency divider 14 shown in FIG. 1 as a component of matching unit 13 can then be eliminated.

By providing a clock input 12c to a clocked DC converter 12 according to the invention and supplying the clock input with a control signal y0′, which depends on the high-frequency output signal y0 of circuit unit 11, a circuit arrangement is achieved that—as described in greater detail hereinafter—improves several properties of voltage-controlled circuit unit 11 (disturbance sensitivity, quality, etc.) and, nevertheless, can be integrated simply and cost-effectively into a semiconductor circuit (IC). Control voltages vt1 with a large voltage swing relative to the supply voltage are generated in particular according to the invention, without a quartz oscillator being necessary for this.

To adjust the frequency f0, VCO 15 preferably comprises a capacitive unit with an adjustable (variable) capacitance value. In other embodime provided whose inductance value is adjustable.

The capacitive unit has, e.g., a unit with a continuously variable capacitance value, such as, e.g., a varactor, capacitive, or MOS diode (metal oxide semiconductor), or a MEM varactor (microelectromechanical), and/or a unit with a stepwise variable (switchable) capacitance value, which is made, e.g., as a switched MIM capacitor (metal-insulator-metal), switched polycap, or as a switched capacitor bank (capacitive digital-to-analog converter, CDAC). The capacitive unit preferably has a varactor diode, which is tunable with a PLL-controlled analog control voltage and is not shown in FIG. 1, and a capacitor bank (CDAC) switched by control voltages vt1.

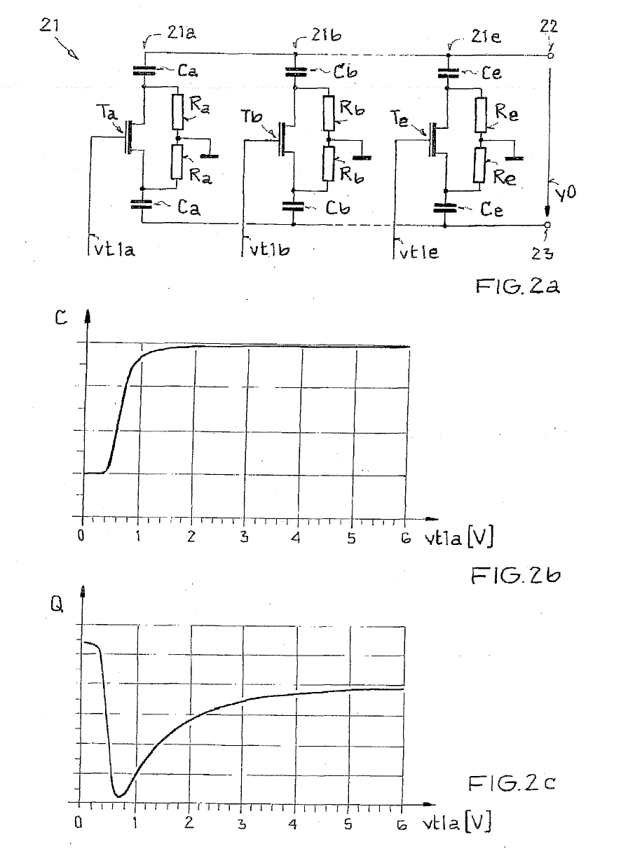

FIG. 2 shows a circuit diagram (FIG. 2a) of a switched capacitor bank 21 with a total of five stages and the properties (FIGS. 2b-c) of a single stage of capacitor bank 21.

According to FIG. 2a, between terminals 22 and 23, switched capacitor bank 21 has a total of five parallel-connected series circuits 21a, 21b, . . . , 21e, each comprising two MIM capacitors and the operating segment of a field-effect transistor; here, each stage is controlled by an assigned control voltage vt1a, vt1b, . . . , vt1e, in which the gate terminal of the transistor of the specific stage is supplied with the corresponding control voltage vt1a, vt1b. . . vt1e. The high-frequency output signal y0 (see FIG. 1) preferably corresponds to the voltage tapped between terminals 22 and 23.

FIGS. 2b and 2c show the capacitance value C or the quality Q, respectively, of first stage 21a of switched capacitor bank 21 as a function of its control voltage vt1a.

It is evident from FIG. 2b that the increase in the capacitance value C of first stage 21a at a control voltage value vt1a of, for example, 6 V is lower than at a value of, for example, 3 V. This means that the capacitance value C of first stage 21a is influenced less greatly by additive disturbances, such as, e.g., noise, at vt1a=6 V than at vt1a=3 V. Additive disturbances in the control voltages vt1a, . . . , vt1e therefore modulate the frequency f0 of the output signal y0 less greatly at higher voltage values or voltage swings of the control voltages than at lower voltage values or swings. Circuit arrangement 10, previously described with reference to FIGS. 1 and 2, is therefore especially robust (insensitive) to additive disturbance, such as, e.g., noise.

Furthermore, capacitance value C of first stage 21a is higher at a control voltage value vt1a of, for example, 6 V than at a value of, for example, 3 V, so that circuit unit 11 advantageously has a higher (broader) tuning range.

It is evident from FIG. 2c that the quality Q of first stage 21a is considerable greater at a control voltage vt1a of, for example, 6 V than at a value of, for example, 3 V. This means that the quality of capacitive unit 21 and thereby VCO 15 is higher at higher voltage values or voltage swings of the control voltages than at lower voltage values or swings. Circuit arrangement 10, previously described with reference to FIGS. 1 and 2, is therefore especially low-loss and energy-efficient.

Due to the closed loop from the DC converter to the circuit unit and from said unit again to the DC converter, the disturbance portion and noise portion in the control signals and thereby also in the output signal are especially small, so that improved properties of the circuit unit result overall.

For these reasons, the properties of the voltage-controlled circuit unit improve both during small-signal and large-signal operation.

FIG. 3 shows a block diagram of a second exemplary embodiment of a circuit arrangement of the invention with a voltage-controlled amplifier.

Integratable circuit arrangement 20 comprises a controllable circuit unit 11, a clocked DC converter (DC/DC) 12, and a matching unit 13.

DC converter 12 is connected on the input side via its clock input 12c and matching unit 13 to an output 11b of circuit unit 11. On the output side, DC converter 12 is connected via an output 12b to a control input 11a of circuit unit 11.

Controllable circuit unit 11 generates an output signal y0, dependent on at least one control voltage vt1, and provides it at its output 11b. In this exemplary embodiment, circuit unit 11, for example, has a voltage-controlled amplifier 18, which generates an amplified output signal y0 with an adjustable center frequency from a high-frequency input signal x0; in this case, the output signal y0, for example, at a value of the control voltage of vt1=6 V has a central frequency f0 of 2.4 GHz and at a value vt1=0 V, a central frequency f0 of 3.5 GHz.

To adjust the frequency f0, amplifier 18 preferably comprises a capacitive unit with an adjustable (variable) capacitance value. This capacitive unit preferably comprises a switched capacitor, which corresponds, e.g., to a stage of the CDAC shown in FIG. 2a.

DC converter 12 converts the two input-side potential values 3 V (Vdd) and 0 V (ground) into an output-side potential value of 6 V, if a control signal is applied at its clock input 12c. If, in contrast, there is no signal at clock input 12c, it generates an output-side potential value of 0 V. At its output 12b, DC converter 12 provides the control voltage vt1 with the particular potential value of 6 V or 0 V to control circuit unit 11.

DC converter 12 generates the control voltage vt1 therefore again depending on a control signal y0′ applied at its clock input 12c. The control signal y0′ supplied to clock input 12c depends on the high-frequency output signal y0 of circuit unit 11 and is derived from it by matching unit 13.

In this exemplary embodiment, matching unit 13 has a switch 16 and an inductor L2, so that the control signal y0′ also depends on the control voltage Vs controlled by switch 16. Switch 16 is opened or closed depending on the value of the control voltage Vs, so that the connection of output 11b to clock input 12c is interrupted or closed, respectively. With the use of inductor L2, the signal amplitude can be increased in turn advantageously, provided switch 16 is closed.

In other embodiments, switch 16 can be disposed within DC converter 12 and analogous to the first exemplary embodiment, depending on a control voltage Vs or Vt2, switch, e.g., between two potential values.

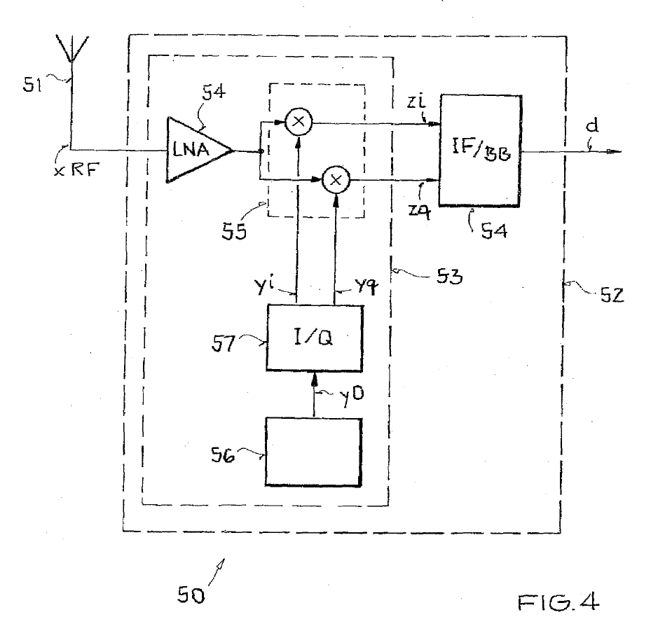

FIG. 4 shows a simplified block diagram of a transmitting/receiving device for a data transmission system according to IEEE 802.16 (WiMax, worldwide interoperability for microwave access).

Transmitting/receiving device 50 has an antenna 51 and a transmitting/receiving unit 52 (transceiver) connected to the antenna. Transmitting/receiving unit 52 comprises an HF front-end circuit 53, connected to the antenna, and an IF/BB signal processing unit 54 connected downstream. Transmitting/receiving unit 52 further comprises a transmission path, which is not shown in FIG. 4 and is connected to antenna 51.

HF front-end-circuit 53 amplifies a high-frequency radio signal xRF, which is received by antenna 51 and lies spectrally in the microwave range between 3.4 and 3.6 GHz, and converts (transforms) it into a quadrature signal z in an intermediate frequency range (intermediate frequency, IF) or in the baseband range (zero IF). The quadrature signal z is a complex-valued signal with an in-phase component zi and a quadrature phase component zq.

IF/BB signal processing unit 54 filters the quadrature signal z and shifts it perhaps spectrally into the baseband, demodulates the baseband signal, and detects the data d contained therein and originally transmitted by another transmitting/receiving device.

HF front-end circuit 53 has an amplifier 54 (low noise amplifier, LNA), connected to antenna 51, for amplifying the high-frequency radio signal xRF and a quadrature mixer 55, connected downstream, for converting the amplified signal into the quadrature signal z. Furthermore, HF front-end circuit 53 has a circuit arrangement 56 of the invention and an I/Q generator 57, connected downstream, which is connected to quadrature mixer 55 on the output side.

Circuit arrangement 56 comprises a voltage-controlled oscillator (VCO), whose frequency is adjusted relatively roughly with the use of control voltages vt1 and fine tuned with the use of other (optionally PLL-controlled) control voltages. Circuit arrangement 56 is realized preferably according to the exemplary embodiments described previously with reference to FIGS. 1 and 2.

I/Q generator 57 derives from local oscillator signal y0 of circuit arrangement 56 a differential in-phase signal yi and a differential quadrature phase signal yq, phase-shifted by 90 degrees. Optionally, I/Q generator 57 comprises a frequency divider, amplifier elements, and/or a unit that assures that the phase offset of the signals yi and yq is 90 degrees as precisely as possible.

In other advantageous embodiments, in the transmission path, HF front-end switch 53 has an amplifier (power amplifier), not shown in FIG. 4, which is a component of a circuit arrangement, which is realized according to the exemplary embodiment previously described with reference to FIG. 3.

HF front-end circuit 53 and thereby the at least one circuit arrangement of the invention and perhaps parts of the IF/BB signal processing unit 54 are preferably a component of an integrated circuit (IC), which is formed, e.g., as a monolithically integrated circuit using a standard technology, for example, a BiCMOS technology, as a hybrid circuit (thin or thick-layer technology), or as a multilayer ceramic circuit.

The circuit arrangement described heretofore with use of exemplary embodiments can be used advantageously in highly diverse applications, such as, e.g., in oscillator, amplifier, and filter circuits (adjustable transfer function, bandwidth, etc.).

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. An integratable circuit arrangement comprising:
a circuit unit controllable by at least one control voltage to provide a high-frequency output signal dependent on the at least one control voltage; and
a clocked DC converter for providing the at least one control voltage based on a control signal applied at a clock input,
wherein the circuit arrangement supplies the clock input with the control signal based on the high-frequency output signal.

2. The circuit arrangement according to claim 1, wherein the circuit arrangement is formed to provide the at least one control voltage in such a way that it has a maximum value, in terms of amount, which exceeds a value of a supply voltage of the circuit arrangement.

3. The circuit arrangement according to claim 2, wherein the circuit arrangementis formed to supply operating power to the DC converter and/or the circuit unit by a supply voltage.

4. The circuit arrangement according to claim 1, further comprising a matching unit connected to the circuit unit and to the clock input for changing an amplitude and/or a frequency of the high-frequency output signal and for providing the resulting control signal.

5. The circuit arrangement according to claim 4, wherein the matching unit derives from the output signal having a first amplitude, a control signal with a second amplitude, which is greater than the first amplitude.

6. The circuit arrangement according to claim 4, wherein the matching unit has a frequency divider, which divides the frequency of the high-frequency output signal.

7. The circuit arrangement according to claim 1, wherein the circuit arrangement is formed to supply the clock input with the high-frequency output signal.

8. The circuit arrangement according to claim 1, wherein the circuit arrangement is formed to derive the control signal from the high-frequency output signal.

9. The circuit arrangement according to claim 1, wherein a first frequency of the high-frequency. output signal with an integer multiple coincides with a second frequency of the control signal.

10. The circuit arrangement according to claim 1, wherein a first frequency of the high-frequency output signal coincides with a second frequency of the control signal or with the twofold value of the second frequency.

11. The circuit arrangement according to claim 1, wherein the circuit unit has a capacitive unit, whose capacitance value is adjustable by at least one control voltage.

12. The circuit arrangement according to claim 11, wherein the capacitive unit has at least one metal-insulator-metal capacitor, varactor, a switched capacitor bank, and/or a microelectromechanical varactor.

13. The circuit arrangement according to claim 1, wherein the circuit unit has at least one transistor and/or at least one microelectromechanical switch, which can be controlled by at least one control voltage.

14. The circuit arrangement according to claim 1, wherein the circuit unit has an inductive unit, whose inductance value is adjustable by at least one control voltage.

15. The circuit arrangement according to claim 1, wherein the circuit unit has an oscillator, an amplifier, or a filter, which is controlled by at least one control voltage.

16. The circuit arrangement according to claim 1, wherein the DC converter is formed to provide at least one control voltage with a voltage swing, which exceeds an input-side voltage swing.

17. The circuit arrangement according to claim 1, wherein the DC converter is designed as a boost converter or as an inverting boost converter.

18. An integrated circuit, particularly for a transmitting/receiving device of a data transmission system according to IEEE 802.16, having at least one circuit arrangement comprising:
a circuit unit controllable by at least one control voltage to provide a high-frequency output signal dependent on the at least one control voltage; and
a clocked DC converter for providing the at least one control voltage based on a control signal applied at a clock input,
wherein the circuit arrangement supplies the clock input with the control signal based on the high-frequency output signal.

19. The integrated circuit according to claim 18, wherein the integrated circuit is designed as a monolithically integrated circuit, as a hybrid circuit, or as a multilayer ceramic circuit.
